(19) United States
(12) Patent Application Publication
(10) Pub. No.: US 2025/0221162 A1
(43) Pub. Date: Jul. 3, 2025

(54) MANUFACTURING METHOD FOR DISPLAY DEVICE

(71) Applicant: Japan Display Inc., Tokyo (JP)

(72) Inventor: Manabu YAMASHITA, Tokyo (JP)

(73) Assignee: Japan Display Inc., Tokyo (JP)

(21) Appl. No.: 18/981,717

(22) Filed: Dec. 16, 2024

(30) Foreign Application Priority Data
Dec. 27, 2023 (JP) 2023-221237

(51) Int. Cl. H10K 59/12; H10K 59/122; H10K 71/20

(52) U.S. Cl. CPC H10K 59/1201; H10K 59/122; H10K 71/231

(57) ABSTRACT

According to one embodiment, a manufacturing method for a display device includes forming a lower electrode, an inorganic insulating layer and a partition including a lower portion and an upper portion, forming a stacked film including an upper electrode, forming a sealing layer, forming a patterned resist, removing the sealing layer, and removing the upper electrode which is in contact with the lower portion by an etchant. The etchant is a mixture of nitric acid, phosphoric acid and acetic acid. Concentration of the nitric acid is greater than or equal to 26%. Concentration of the phosphoric acid is greater than or equal to 0.5% and less than or equal to 10%. Concentration of the acetic acid is greater than or equal to 0.5% and less than or equal to 15%.

### CROSS-REFERENCE TO RELATED APPLICATIONS

This application is based upon and claims the benefit of priority from Japanese Patent Application No. 2023-221237, filed Dec. 27, 2023, the entire contents of which are incorporated herein by reference.

### FIELD

Embodiments described herein relate generally to a manufacturing method for a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is the schematic cross-sectional view of the display device DSP along the A-B line of FIG. 2.

FIG. 4 is a diagram for explaining the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram showing a configuration example of an etching device 200 for removing an upper electrode UE1 in a simplified manner.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a cross-sectional view showing another configuration example of a mother substrate 100.

FIG. 15 is an experimental result showing the relationship between the composition ratio of an etchant and the exfoliation of an organic layer.

### DETAILED DESCRIPTION

Embodiments described herein aim to provide a manufacturing method for a display device such that the reduction in reliability can be prevented.

In general, according to one embodiment, a manufacturing method for a display device comprises preparing a processing substrate in which a lower electrode, an inorganic insulating layer and a partition are formed, the lower electrode being located above a substrate, the inorganic insulating layer having an aperture overlapping the lower electrode, and the partition including a lower portion located on the inorganic insulating layer and an upper portion located on the lower portion and protruding from a side surface of the lower portion, forming a stacked film including an upper electrode on the lower electrode in the aperture by vapor deposition using the partition as a mask, forming a sealing layer on the stacked film using an inorganic insulating material, forming a patterned resist on the sealing layer, removing the sealing layer exposed from the resist, and removing the stacked film exposed from the resist. The removing the stacked film includes removing the upper electrode which is in contact with the lower portion by an etchant. The etchant is a mixture of nitric acid, phosphoric acid and acetic acid. Concentration of the nitric acid is greater than or equal to 26%. Concentration of the phosphoric acid is greater than or equal to 0.5% and less than or equal to 10%. Concentration of the acetic acid is greater than or equal to 0.5% and less than or equal to 15%.

According to another embodiment, a manufacturing method for a display device comprises preparing a processing substrate in which first and second lower electrodes, an inorganic insulating layer and a partition are formed, the first and second lower electrodes being located above a substrate, the inorganic insulating layer having a first aperture overlapping the first lower electrode and a second aperture overlapping the second lower electrode, and the partition including a lower portion located on the inorganic insulating layer between the first aperture and the second aperture and an upper portion located on the lower portion and protruding from a side surface of the lower portion, forming a stacked film including an upper electrode on the first lower electrode in the first aperture and on the second lower electrode in the second aperture by vapor deposition using the partition as a mask, forming a sealing layer on the stacked film using an inorganic insulating material, forming a patterned resist on the sealing layer located immediately above the first lower electrode, exposing the stacked film which overlaps the second lower electrode by removing the sealing layer exposed from the resist, and exposing the second lower electrode from the second aperture and exposing a side surface of the lower portion facing the second aperture by removing the stacked film exposed from the resist. The removing the stacked film includes removing the upper electrode which is in contact with the lower portion by an etchant. The etchant is a mixture of nitric acid, phosphoric acid and acetic acid. Concentration of the nitric acid is greater than or equal to 26%. Concentration of the phosphoric acid is greater than or equal to 0.5% and less than or equal to 10%. Concentration of the acetic acid is greater than or equal to 0.5% and less than or equal to 15%.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

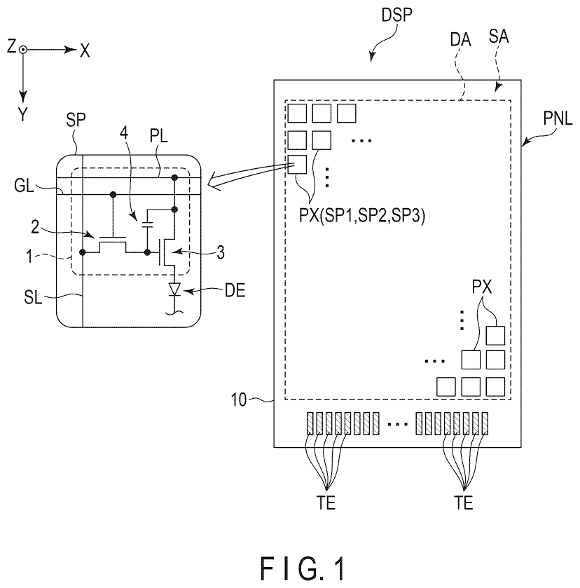

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the present embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element DE.

It should be noted that the configuration of the pixel circuit 1 is not limited to the example shown in the figure. For example, the pixel circuit 1 may comprise more thin-film transistors and capacitors.

The display element DE is an organic light emitting diode (OLED) as a light emitting element, and may be called an organic EL element.

The surrounding area SA comprises a plurality of terminals TE which are unidirectionally arranged. In the example shown in the figure, the terminals TE are arranged in the first direction X. Each of the terminals TE extends in the second direction Y. However, the configuration is not limited to this example. For example, these terminals TE are electrically connected to a flexible printed circuit or an IC chip.

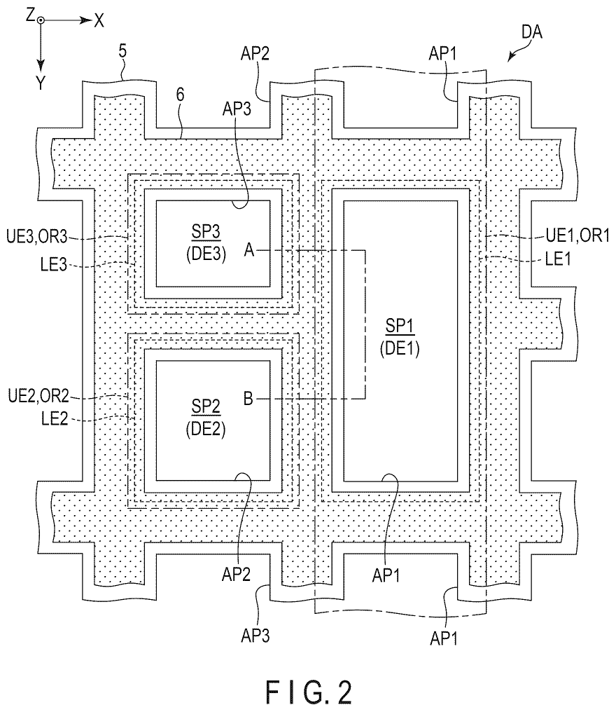

FIG. 2 is a diagram showing an example of the layout of subpixels SP1, SP2 and SP3.

In the example shown in the figure, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 has apertures AP1, AP2 and AP3 in subpixels SP1, SP2 and SP3, respectively. The inorganic insulating layer 5 having these apertures AP1, AP2 and AP3 may be called a rib.

The partition 6 overlaps the inorganic insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the inorganic insulating layer 5. The partition 6 is conductive and is electrically connected to, of the terminals TE shown in FIG. 1, each terminal TE having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The lower electrode LE1, the organic layer OR1 and the upper electrode UE1 are surrounded by the partition 6 in plan view. The peripheral portion of each of the organic layer OR1 and the upper electrode UE1 overlaps the inorganic insulating layer 5 in plan view. The organic layer OR1 includes a light emitting layer which emits light in, for example, a blue wavelength range.

The display element DE2 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The lower electrode LE2, the organic layer OR2 and the upper electrode UE2 are surrounded by the partition 6 in plan view. The peripheral portion of each of the organic layer OR2 and the upper electrode UE2 overlaps the inorganic insulating layer 5 in plan view. The organic layer OR2 includes a light emitting layer which emits light in, for example, a green wavelength range.

The display element DE3 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The lower electrode LE3, the organic layer OR3 and the upper electrode UE3 are surrounded by the partition 6 in plan view. The peripheral portion of each of the organic layer OR3 and the upper electrode UE3 overlaps the inorganic insulating layer 5 in plan view. The organic layer OR3 includes a light emitting layer which emits light in, for example, a red wavelength range.

In the example shown in the figure, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers or upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

The lower electrode LE1 is electrically connected to the pixel circuit 1 (see FIG. 1) of subpixel SP1. The lower electrode LE2 is electrically connected to the pixel circuit 1 of subpixel SP2. The lower electrode LE3 is electrically connected to the pixel circuit 1 of subpixel SP3.

In the example shown in the figure, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

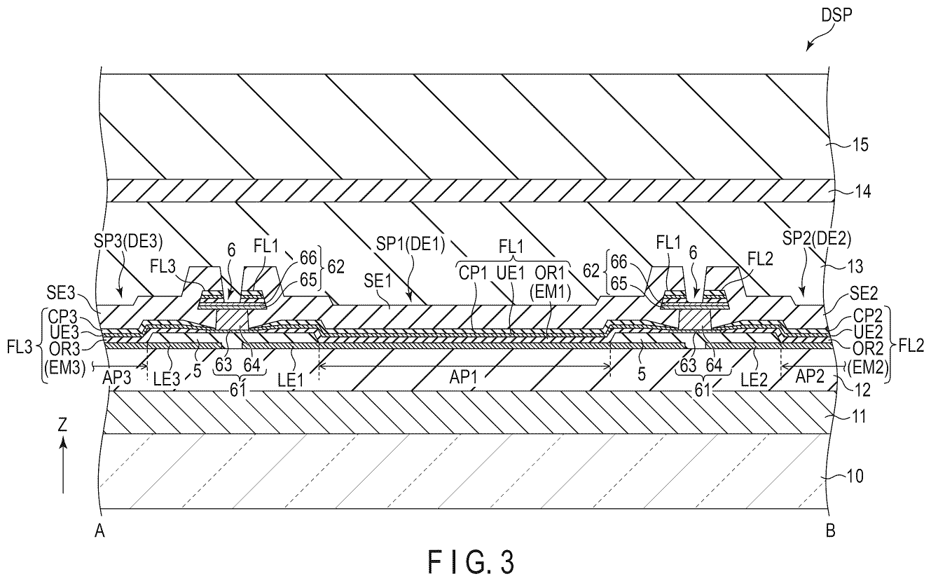

FIG. 3 is the schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The lower electrodes LE1, LE2 and LE3 are connected to the pixel circuits 1 of subpixels SP1, SP2 and SP3, respectively, through contact holes provided in the insulating layer 12. It should be noted that the contact holes of the insulating layer 12 are omitted in FIG. 3.

The partition 6 includes a conductive lower portion 61 provided on the inorganic insulating layer 5, and an upper portion 62 provided on the lower portion 61. The upper portion 62 has a width greater than that of the lower portion 61. The both end portions of the upper portion 62 protrude relative to the side surfaces of the lower portion 61. This shape of the partition 6 is called an overhang shape.

In the example shown in the figure, the lower portion 61 has a first conductive layer 63 provided on the inorganic insulating layer 5 and a second conductive layer 64 provided on the first conductive layer 63. For example, the first conductive layer 63 is formed so as to be thinner than the second conductive layer 64. The both end portions of the first conductive layer 63 protrude from the side surfaces of the second conductive layer 64.

The upper portion 62 has a first thin film 65 provided on the second conductive layer 64 and a second thin film 66 provided on the first thin film 65. The both end portions of the first thin film 65 and the second thin film 66 protrude from the side surfaces of the second conductive layer 64.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example shown in the figure, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively. It should be noted that the cap layers CP1, CP2 and CP3 may be omitted.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

In the example shown in the figure, part of the stacked film FL1 is located on the partition 6 around subpixel SP1 and spaced apart from the stacked film FL1 located in the aperture AP1 (in other words, the portion which constitutes the display element DE1).

Similarly, part of the stacked film FL2 is located on the partition 6 around subpixel SP2 and spaced apart from the stacked film FL2 located in the aperture AP2 (in other words, the portion which constitutes the display element DE2).

Similarly, part of the stacked film FL3 is located on the partition 6 around subpixel SP3 and spaced apart from the stacked film FL3 located in the aperture AP3 (in other words, the portion which constitutes the display element DE3).

It should be noted that the stacked films FL1, FL2 and FL3 located on the partition 6 may be omitted in some cases. In this case, a cavity is formed between the sealing layers SE1, SE2 and SE3 and the partition 6.

Each of the end portions of the sealing layers SE1, SE2 and SE3 is located above the partition 6. In the example shown in the figure, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The partition 6 and the sealing layers SE1, SE2 and SE3 are covered with a resin layer 13. When cavities are formed between the sealing layers SE1, SE2 and SE3 and the partition 6, these cavities are filled with the resin layer 13. The resin layer 13 is covered with a sealing layer 14. The sealing layer 14 is covered with a resin layer 15.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The first conductive layer 63 is formed of, for example, a titanium-based material such as titanium or a titanium compound. The second conductive layer 64 is formed of a material which is different from the first conductive layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material which is different from that of the lower portion 61. The first thin film 65 is formed of, for example, a titanium-based material such as titanium or a titanium compound. The second thin film 66 is formed of, for example, an oxide conductive material such as indium tin oxide (ITO).

Each of the lower electrodes LE1, LE2 and LE3 is, for example, a multilayer body including a transparent layer formed of an oxide conductive material such as indium tin oxide (ITO) and a reflective layer formed of a metal material such as silver. For example, each of the lower electrodes LE1, LE2 and LE3 is a multilayer body including a reflective layer between a pair of transparent layers.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, insulating layer 12 and inorganic insulating layer 5 shown in the figure are provided over the display area DA and the surrounding area SA.

Now, this specification explains the manufacturing method of the display device DSP. Regarding each figure for explaining the manufacturing method, the illustration of the lower side of the insulating layer 12 is omitted.

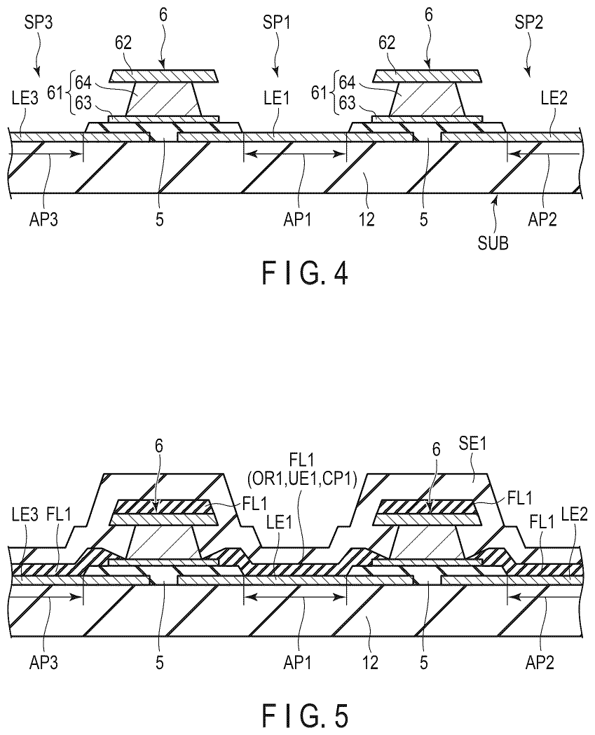

First, as shown in FIG. 4, a processing substrate SUB comprising the lower electrodes LE1, LE2 and LE3, the inorganic insulating layer 5 and the partition 6 is prepared. The process of preparing the processing substrate SUB includes the following processes. The circuit layer 11 and the insulating layer 12 are formed over the display area DA and the surrounding area SA on the substrate 10. Subsequently, the lower electrode LE1 of subpixel SP1, the lower electrode LE2 of subpixel SP2 and the lower electrode LE3 of subpixel SP3 are formed on the insulating layer 12. Subsequently, the inorganic insulating layer 5 which covers the peripheral portions of the lower electrodes LE1, LE2 and LE3 is formed. The inorganic insulating layer 5 is formed of silicon oxide, silicon nitride, silicon oxynitride, etc. Subsequently, the partition 6 which has the lower portion 61 located on the inorganic insulating layer 5 and the upper portion 62 located on the lower portion 61 is formed. The first conductive layer 63 of the lower portion 61 and the upper portion 62 protrude from the side surfaces of the second conductive layer 64 of the lower portion 61. The first conductive layer 63 is formed of a titanium-based material, and the second conductive layer 64 is formed of an aluminum-based material.

It should be noted that the process of forming the apertures AP1, AP2 and AP3 in the inorganic insulating layer 5 may be performed either before the partition 6 is formed or after the partition 6 is formed.

Subsequently, the display element DE1 is formed.

First, as shown in FIG. 5, the stacked film FL1 including the organic layer OR1, the upper electrode UE1 and the cap layer CP1 is formed. The process of forming the stacked film FL1 includes the process of forming the organic layer OR1 which is in contact with the lower electrode LE1 in the aperture AP1, the process of forming the upper electrode UE1 which covers the organic layer OR1 and is in contact with the lower portion 61 of the partition 6, and the process of forming the cap layer CP1 located on the upper electrode UE1. The process of forming the organic layer OR1 includes the process of forming each of the hole injection layer, the hole transport layer, the electron blocking layer, the light emitting layer, the hole blocking layer, the electron transport layer, the electron injection layer and the like. The upper electrode UE1 is formed of a mixture of magnesium and silver.

Each of the organic layer OR1, the upper electrode UE1 and the cap layer CP1 is formed by vapor deposition using the partition 6 as a mask. The stacked film FL1 is divided into a plurality of portions by the partition 6 having an overhang shape. These organic layer OR1, upper electrode UE1 and cap layer CP1 are continuously formed while maintaining a vacuum environment. This stacked film FL1 is formed on the lower electrode LE2 and the lower electrode LE3 as well.

Subsequently, the sealing layer SE1 is formed on the stacked film FL1 by depositing an inorganic insulating material. The sealing layer SE1 is formed by chemical vapor deposition (CVD). The sealing layer SE1 continuously covers the portions into which the stacked film FL1 is divided, and the partition 6.

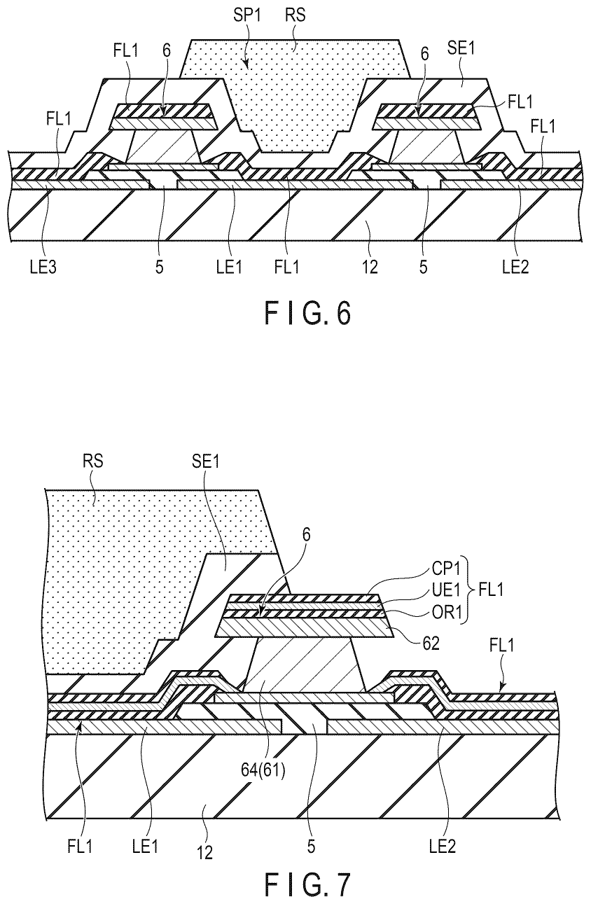

Subsequently, as shown in FIG. 6, a resist RS patterned into a predetermined shape is formed on the sealing layer SE1. The resist RS overlaps subpixel SP1 and part of the partition 6 around subpixel SP1.

Subsequently, the sealing layer SE1 and the stacked film FL1 exposed from the resist RS are removed in series by performing etching using the resist RS as a mask. This etching process is explained in detail with reference to an enlarged cross-sectional view including the lower electrode LE1 and the lower electrode LE2.

First, as shown in FIG. 7, the sealing layer SE1 exposed from the resist RS is removed. By this process, on the partition 6, part of the cap layer CP1 is exposed, and the cap layer CP1 located on the lower electrode LE2 is exposed. Although not shown in the figure, the cap layer CP1 located on the lower electrode LE3 is also exposed. In addition, in the partition 6, the side surface of the lower portion 61 (or the second conductive layer 64) facing the lower electrode LE2 is also exposed.

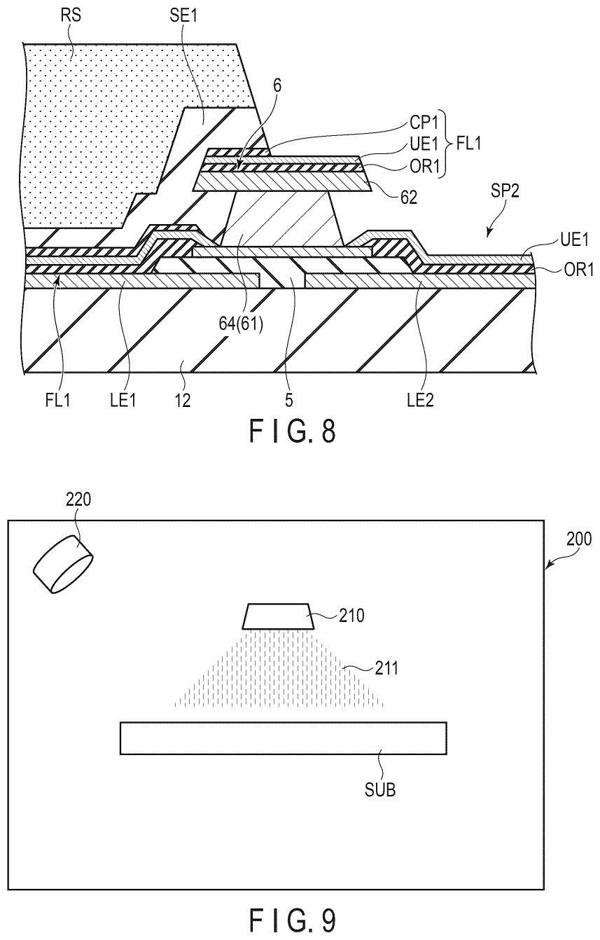

Subsequently, as shown in FIG. 8, the cap layer CP1 exposed from the resist RS is removed. By this process, on the partition 6, part of the upper electrode UE1 is exposed, and the upper electrode UE1 located on the lower electrode LE2 is exposed. Although not shown in the figure, the upper electrode UE1 located on the lower electrode LE3 is also exposed.

Subsequently, the upper electrode UE1 exposed from the resist RS is removed. The process of removing the upper electrode UE1 is performed by wet etching using a predetermined etchant.

FIG. 9 is a diagram showing a configuration example of an etching device 200 for removing the upper electrode UE1 in a simplified manner.

The etching device 200 comprises a nozzle 210 which injects an etchant 211 and a light source 220 which illuminates the inside of the device.

The etchant 211 is a mixture of nitric acid, phosphoric acid and acetic acid. The concentration of nitric acid is greater than or equal to 26%. The concentration of phosphoric acid is greater than or equal to 0.5% and less than or equal to 10%. The concentration of acetic acid is greater than or equal to 0.5% and less than or equal to 15%. In this specification, the term “concentration” refers to a volume percent concentration, and its unit may be referred to as vol %.

The light source 220 has a bright line spectrum in wavelengths greater than or equal to 550 nm. For the light source 220, for example, a low pressure sodium vapor lamp should be preferably used.

When the processing substrate SUB from which the cap layer CP1 is removed is carried in the etching device 200, the etchant 211 is injected from the nozzle 210 to the processing substrate SUB. The upper electrode UE1 exposed from the resist RS and the side surface of the lower portion 61 (or the second conductive layer 64) facing the lower electrode LE2 are exposed to the etchant 211.

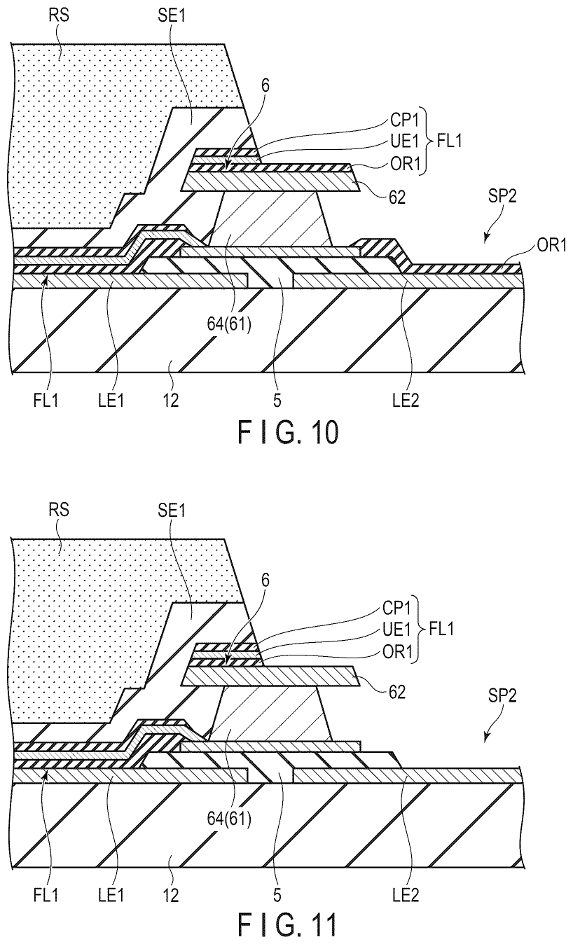

By this process, as shown in FIG. 10, the upper electrode UE1 exposed from the resist RS is removed, and on the partition 6, the organic layer OR1 is partly exposed, and further, the organic layer OR1 located on the lower electrode LE2 is exposed. Although not shown in the figure, the organic layer OR1 located on the lower electrode LE3 is also exposed.

Subsequently, as shown in FIG. 11, the organic layer OR1 exposed from the resist RS is removed. By this process, the upper portion 62 of the partition 6 is partly exposed, and further, the lower electrode LE2 is exposed.

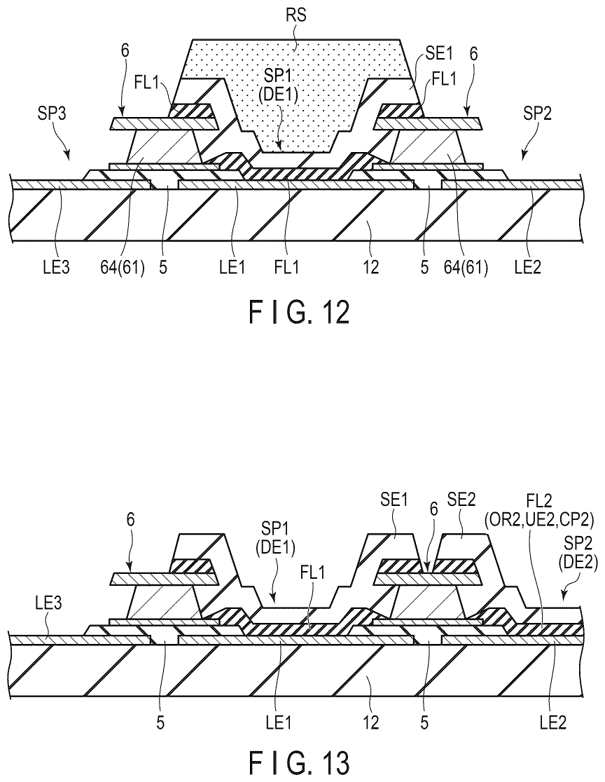

As shown in FIG. 12, the stacked film FL1 covered with the resist RS remains in subpixel SP1, and the lower electrode LE2 is exposed in subpixel SP2, and the lower electrode LE3 is exposed in subpixel SP3.

Subsequently, the resist RS is removed. By this process, the display element DE1 is formed in subpixel SP1.

Subsequently, as shown in FIG. 13, the display element DE2 is formed. The procedure of forming the display element DE2 is similar to that of forming the display element DE1. Specifically, the stacked film FL2 is formed by forming the organic layer OR2 including the light emitting layer EM2, the upper electrode UE2 and the cap layer CP2 in order on the lower electrode LE2. Subsequently, the sealing layer SE2 is formed on the stacked film FL2. Subsequently, a resist is formed on the sealing layer SE2. The sealing layer SE2, the cap layer CP2, the upper electrode UE2 and the organic layer OR2 are patterned by etching using the resist as a mask. After this patterning, the resist is removed. In this manner, the display element DE2 is formed in subpixel SP2, and the lower electrode LE3 of subpixel SP3 is exposed.

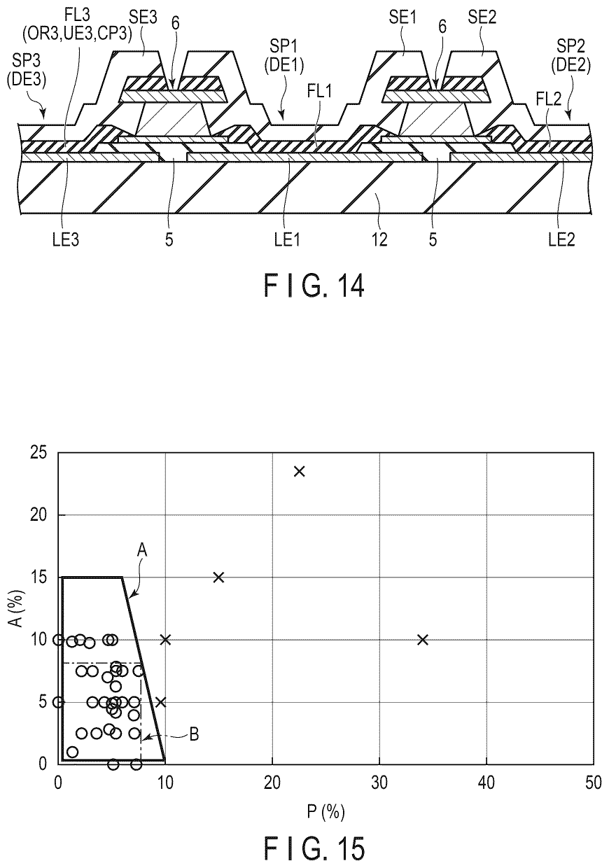

Subsequently, as shown in FIG. 14, the display element DE3 is formed. The procedure of forming the display element DE3 is similar to that of forming the display element DE1. Specifically, the stacked film FL3 is formed by forming the organic layer OR3 including the light emitting layer EM3, the upper electrode UE3 and the cap layer CP3 in order on the lower electrode LE3. Subsequently, the sealing layer SE3 is formed on the stacked film FL3. Subsequently, a resist is formed on the sealing layer SE3. The sealing layer SE3, the cap layer CP3, the upper electrode UE3 and the organic layer OR3 are patterned by etching using the resist as a mask. After this patterning, the resist is removed. By this process, the display element DE3 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

FIG. 15 is an experimental result showing the relationship between the composition ratio of an etchant and the exfoliation of an organic layer.

In the etchant, the concentration of nitric acid is set so as to be 30%. In the figure, the horizontal axis corresponds to the concentration of phosphoric acid, and the vertical axis corresponds to the concentration of acetic acid. The time for which the processing substrate SUB is exposed to the etchant is 15 to 300 seconds. In the figure, the symbol “o” indicates that no exfoliation occurs in the organic layer when the processing substrate SUB is exposed to the etchant. In the figure, the symbol “x” indicates that exfoliation occurs in the organic layer when the processing substrate SUB is exposed to the etchant.

In area A surrounded by the solid line in the figure, generally, the exfoliation of the organic layer is not confirmed. At this time, the concentration of nitric acid is greater than or equal to 30%, and the concentration of phosphoric acid is greater than or equal to 0.5% and less than or equal to 10%, and the concentration of acetic acid is greater than or equal to 0.5% and less than or equal to 15%. Further, in area B surrounded by the one-dot chain line in the figure, the exfoliation of the organic layer is not confirmed at all. At this time, the concentration of nitric acid is greater than or equal to 308, and the concentration of phosphoric acid is greater than or equal to 0.5% and less than or equal to 8%, and the concentration of acetic acid is greater than or equal to 0.5% and less than or equal to 8%.

Here, this specification explains problems caused by the exfoliation of the organic layer when the upper electrode is removed.

It is assumed that the organic layer is formed by vapor deposition and adheres tightly to the lower electrode by an electric effect. For this reason, if the ion density of the etchant is increased, the electrostatic action between the lower electrode and the organic layer is blocked, and the adherence between them is decreased, thereby easily causing the exfoliation of the organic layer.

The second conductive layer 64 included in the lower portion 61 of the partition 6 is formed of an aluminum-based material. It is necessary to prevent undesired etching of the second conductive layer 64 when it is exposed to the etchant. Therefore, in order to accelerate the oxidation of the surface of the second conductive layer 64, the etchant needs to contain nitric acid which is a strong acid having a concentration of 26% or greater (preferably 30% or greater).

When this etchant reacts with the upper electrode formed of a mixture of magnesium and silver, it is ionized into nitric acid ions (NO₃−) and silver ions (Ag+). The ionization tendency of silver is lower than that of aluminum. Therefore, silver ions receive electrons from aluminum and are precipitated as silver, and aluminum flows out as ions.

When the organic layer exfoliates in the process of etching of the upper electrode, the lower electrode is exposed, and a battery effect is caused between the lower electrode and the upper electrode via the etchant. The exchange of electrons described above is further facilitated by the battery effect. Thus, when the second conductive layer 64 of the partition 6 is exposed to the etchant, aluminum is excessively eluted, and the side surface of the second conductive layer 64 is retracted. In some cases, the etchant may permeate the second conductive layer 64, and thus, a cavity may be formed in the second conductive layer 64. This phenomenon is caused in the side surface of the second conductive layer 64 facing the display elements DE2 and DE3. Thus, poor connection occurs between the upper electrode and the second conductive layer 64 in the display elements DE2 and DE3. Further, when a cavity is generated, the organic layer is degraded in the display elements DE2 and DE3 by moisture remaining in the cavity. Moreover, when the precipitated silver grows in the partition 6, the sealing performance is degraded in the display elements DE2 and DE3.

Therefore, the prevention of the exfoliation of the organic layer is very important when the upper electrode is etched. For example, in the process of forming the display element DE1, the organic layer OR1 is required to cover the lower electrodes LE2 and LE3 when the upper electrode UE1 is etched. In the process of forming the display element DE2, the organic layer OR2 is required to cover the lower electrode LE3 when the upper electrode UE2 is etched.

In the embodiment, a mixture of phosphoric acid having a concentration of 0.5% or greater and 10% or less and acetic acid having a concentration of 0.5% or greater and 15% or less in addition to the nitric acid described above is used as the etchant. The phosphoric ions (PO₄³⁻) contained in the etchant are easily bonded to the silver ions contained in the etchant. Thus, the silver ions contained in the etchant can be reduced, and the exchange of electrons between silver ions and aluminum is prevented, thereby preventing the precipitation of silver. The acetic acid contained in the etchant exerts an effect as a surfactant and can prevent the insufficiency of etching of the upper electrode.

Regarding phosphoric acid and acetic acid, the concentration should be preferably low to the extent that the above function can be exerted. When the concentration of each of the phosphoric acid and acetic acid contained in the etchant is high, the ion density in the etchant is increased, and as described above, the electrostatic action between the lower electrode and the organic layer is blocked, thereby easily causing the exfoliation of the organic layer. Thus, the concentration of phosphoric acid is less than or equal to 10%, and should be preferably less than or equal to 88. The concentration of acetic acid is less than or equal to 158, and should be preferably less than or equal to 8%.

By applying this etchant, the exfoliation of the organic layer is prevented in the process of etching the upper electrode. This configuration can prevent the excessive retraction of the side surface of the second conductive layer 64, the formation of a cavity in the second conductive layer 64 and undesired precipitation of silver described above. Therefore, the poor connection between the upper electrode and the second conductive layer 64 in the display elements DE2 and DE3, the degradation of the organic layer in the display elements DE2 and DE3 and the degradation of the sealing performance in the display elements DE2 and DE3 can be prevented, thereby preventing the reduction in reliability.

The light source 220 of the etching device 200 has a bright line spectrum in wavelengths greater than or equal to 550 nm. The silver phosphate generated by the phosphoric ions and silver ions contained in the etchant is known to absorb and resolve light having wavelengths shorter than 550 nm. Thus, the application of the light source 220 described above prevents the resolution of silver phosphate, and thus, can prevent the precipitation of silver.

The inventor considered the etching time for which the processing substrate SUB is exposed to the etchant in various ways within the range of 15 to 300 seconds. According to this consideration, to prevent the precipitation of silver, the etching time should be preferably as short as possible, and should be preferably less than or equal to 120 seconds. To prevent the insufficiency of etching of the upper electrode, the etching time should be preferably as long as possible, and should be preferably greater than or equal to 60 seconds.

In the embodiment described above, for example, in the inorganic insulating layer 5, the aperture AP1 corresponds to a first aperture, and the aperture AP2 corresponds to a second aperture. The lower electrode LE corresponds to a first lower electrode, and the lower electrode LE2 corresponds to a second lower electrode. The organic layer OR1 corresponds to a first organic layer, and the organic layer OR2 corresponds to a second organic layer. The upper electrode UE1 corresponds to a first upper electrode, and the upper electrode UE2 corresponds to a second upper electrode.

As described above, the embodiment can provide a manufacturing method for a display device such that the reduction in reliability can be prevented.

All of the manufacturing methods for display devices that can be implemented by a person of ordinary skill in the art through arbitrary design changes to the manufacturing method described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing method for a display device, the method comprising:
preparing a processing substrate in which a lower electrode, an inorganic insulating layer and a partition are formed, the lower electrode being located above a substrate, the inorganic insulating layer having an aperture overlapping the lower electrode, and the partition including a lower portion located on the inorganic insulating layer and an upper portion located on the lower portion and protruding from a side surface of the lower portion;
forming a stacked film including an upper electrode on the lower electrode in the aperture by vapor deposition using the partition as a mask;
forming a sealing layer on the stacked film, using an inorganic insulating material;
forming a patterned resist on the sealing layer;
removing the sealing layer exposed from the resist; and
removing the stacked film exposed from the resist, wherein
the removing the stacked film includes removing the upper electrode which is in contact with the lower portion by an etchant,
the etchant is a mixture of nitric acid, phosphoric acid and acetic acid,
concentration of the nitric acid is greater than or equal to 26%,
concentration of the phosphoric acid is greater than or equal to 0.5% and less than or equal to 10%, and
concentration of the acetic acid is greater than or equal to 0.5% and less than or equal to 15%.

2. The manufacturing method of claim 1, wherein
the concentration of the phosphoric acid is less than or equal to 8%.

3. The manufacturing method of claim 2, wherein
the concentration of the acetic acid is less than or equal to 8%.

4. The manufacturing method of claim 3, wherein
the concentration of the nitric acid is greater than or equal to 30%.

5. The manufacturing method of claim 1, wherein
a time for removing the upper electrode by the etchant is greater than or equal to 60 seconds and less than or equal to 120 seconds.

6. The manufacturing method of claim 1, wherein
the removing the upper electrode by the etchant is performed with a light source having a bright line spectrum in wavelengths greater than or equal to 550 nm.

7. The manufacturing method of claim 6, wherein
a sodium vapor lamp is used as the light source.

8. The manufacturing method of claim 1, wherein
in the lower portion, a first conductive layer located on the inorganic insulating layer is formed of a titanium-based material, and a second conductive layer located between the first conductive layer and the upper portion is formed of an aluminum-based material.

9. The manufacturing method of claim 8, wherein
the upper electrode is formed of a mixture of magnesium and silver.

10. The manufacturing method of claim 9, wherein
the forming the stacked film includes:
forming an organic layer including a light emitting layer on the lower electrode;
forming an upper electrode on the organic layer; and
forming a cap layer on the upper electrode,
a part of the lower portion and the cap layer are exposed when the sealing layer is removed, and
in the process of removing the upper electrode by the etchant, the part of the lower portion is exposed to the etchant.

11. A manufacturing method for a display device, the method comprising:
preparing a processing substrate in which first and second lower electrodes, an inorganic insulating layer and a partition are formed, the first and second lower electrodes being located above a substrate, the inorganic insulating layer having a first aperture overlapping the first lower electrode and a second aperture overlapping the second lower electrode, and the partition including a lower portion located on the inorganic insulating layer between the first aperture and the second aperture and an upper portion located on the lower portion and protruding from a side surface of the lower portion;
forming a stacked film including an upper electrode on the first lower electrode in the first aperture and on the second lower electrode in the second aperture by vapor deposition using the partition as a mask;
forming a sealing layer on the stacked film, using an inorganic insulating material;
forming a patterned resist on the sealing layer located immediately above the first lower electrode;
exposing the stacked film which overlaps the second lower electrode by removing the sealing layer exposed from the resist; and
exposing the second lower electrode from the second aperture and exposing a side surface of the lower portion facing the second aperture by removing the stacked film exposed from the resist; wherein
the removing the stacked film includes removing the upper electrode which is in contact with the lower portion by an etchant,
the etchant is a mixture of nitric acid, phosphoric acid and acetic acid,
concentration of the nitric acid is greater than or equal to 26%,
concentration of the phosphoric acid is greater than or equal to 0.5% and less than or equal to 10%, and
concentration of the acetic acid is greater than or equal to 0.5% and less than or equal to 15%.

12. The manufacturing method of claim 11, wherein
the concentration of the phosphoric acid is less than or equal to 8%.

13. The manufacturing method of claim 12, wherein
the concentration of the acetic acid is less than or equal to 8%.

14. The manufacturing method of claim 13, wherein
the concentration of the nitric acid is greater than or equal to 30%.

15. The manufacturing method of claim 11, wherein
a time for removing the upper electrode by the etchant is greater than or equal to 60 seconds and less than or equal to 120 seconds.

16. The manufacturing method of claim 11, wherein
the removing the upper electrode by the etchant is performed with a light source having a bright line spectrum in wavelengths greater than or equal to 550 nm.

17. The manufacturing method of claim 16, wherein
a sodium vapor lamp is used as the light source.

18. The manufacturing method of claim 11, wherein
in the lower portion, a first conductive layer located on the inorganic insulating layer is formed of a titanium-based material, and a second conductive layer located between the first conductive layer and the upper portion is formed of an aluminum-based material.

19. The manufacturing method of claim 18, wherein
the upper electrode is formed of a mixture of magnesium and silver.

20. The manufacturing method of claim 19, wherein
the forming the stacked film includes:
forming an organic layer including a light emitting layer on the lower electrode;
forming an upper electrode on the organic layer; and
forming a cap layer on the upper electrode,
a part of the lower portion and the cap layer are exposed when the sealing layer is removed, and
in the process of removing the upper electrode by the etchant, the part of the lower portion is exposed to the etchant.
